(19) United States
(12) Patent Application Publication
(10) Pub. No.: US 2024/0087843 A1
(43) Pub. Date: Mar. 14, 2024

(54) APPARATUS FOR TREATING SUBSTRATE AND METHOD FOR TREATING SUBSTRATE

(71) Applicant: PSK INC., Hwaseong-si (KR)

(72) Inventors: JONG CHAN LEE, Hwaseong-si (KR); YONG IK OH, Hwaseong-si (KR); JI TAE KWON, Hwaseong-si (KR); SEONG MIN NAM, Hwaseong-si (KR)

(21) Appl. No.: 18/462,385

(22) Filed: Sep. 6, 2023

(30) Foreign Application Priority Data
Sep. 8, 2022 (KR) 10-2022-0114192

(51) Int. Cl. H01J 37/244; H01J 37/32

(52) U.S. Cl. CPC H01J 37/244; H01J 37/32348; H01J 37/32568; H01J 37/32715; H01J 37/32733; H01J 37/3288; H01J 2237/24578; H01J 2237/3341

(57) ABSTRACT

The inventive concept provides a substrate treating method. The substrate treating method includes taking in a substrate to a treating space to mount on a support unit; upwardly moving the support unit after mounting the substrate on the support unit; determining whether the support unit moves normally after the upwardly moving the support unit; and treating the substrate by generating a plasma in the treating space, and wherein at the determining whether the support unit moves normally, before the plasma is generated at the treating space at the treating the substrate, whether a pulse distance matching a predetermined distance data according to a pulse value of a driving unit which pulse-moves a moving body which moves the support unit in a top/down direction, matches a movement distance of the moving body is determined, and an interlock is generated if the pulse distance and the movement distance is different.

### CROSS-REFERENCE TO RELATED APPLICATIONS

A claim for priority under 35 U.S.C. § 119 is made to Korean Patent Application No. 10-2022-0114192 filed on Sep. 8, 2022, in the Korean Intellectual Property Office, the entire contents of which are hereby incorporated by reference.

### BACKGROUND

Embodiments of the inventive concept described herein relate to a substrate treating apparatus, more specifically, a substrate treating apparatus for treating a substrate using a plasma.

When treating a substrate using a plasma, a gap between members forming an electric field and the substrate must be kept constant according to a recipe. In addition, if the gap between the members forming the electric field and the substrate is different from a value according to the recipe, it is difficult for the substrate to be treated accurately according to the recipe, which leads to a decrease in process yield. There are various reasons why the gap between the members forming the electric field and the substrate is different from a value according to the recipe. For example, a defect in an operation of a driving unit for lifting and lowering a support unit supporting the substrate may be a cause. In addition, a cause may be foreign substances generated during a process are attached to the members forming the electric field and deposited. In addition, one cause may be that the members forming the electric field are damaged by the plasma generated during the process. In order to find an exact cause of the gap between the members forming the electric field and the substrate changing the value according to the recipe, parts inside the chamber must be checked individually. This results in an increased maintenance time and a reduced process efficiency.

### SUMMARY

Embodiments of the inventive concept provide a substrate treating apparatus and a substrate treating method for efficiently treating a substrate.

Embodiments of the inventive concept provide a substrate treating apparatus and a substrate treating method on which an effective maintenance is possible.

The technical objectives of the inventive concept are not limited to the above-mentioned ones, and the other unmentioned technical objects will become apparent to those skilled in the art from the following description.

The inventive concept provides a substrate treating apparatus. The substrate treating apparatus includes a housing having a treating space for treating a substrate; a support unit configured to support the substrate within the treating space; a dielectric plate positioned above the support unit facing the support unit; a gap determination unit configured to measure a gap between a substrate supported on the support unit and the dielectric plate; a driving unit configured to pulse-move a moving body which moves the support unit in a top/down direction; a pulse measurement unit configured to record a pulse value of the driving unit; and a displacement measurement unit configured to measure a movement distance of the moving body.

In an embodiment, the substrate treating apparatus further includes at least a pair of view ports formed to face each other on a sidewall of the housing, and wherein the gap measurement unit includes: an irradiation unit installed at any one view point among the view ports and configured to irradiate a light; and a light receiving unit installed at the other view point among the view ports and configured to receive the light.

In an embodiment, the driving unit includes: a ball screw which is screw-coupled to a nut unit formed within the moving body which moves along a guide rail having a top/down lengthwise direction; and a driving motor which pulse-moves the moving body by rotating the ball screw, and wherein the pulse measurement unit includes an encoder which measures a pulse value of the driving motor, and measures a pulse distance which matches a distance data which is predetermined according to the pulse value, and the displacement measurement unit includes: a linear scale positioned adjacent to the guide rail, having a lengthwise direction parallel to a lengthwise direction of the guide rail, and displaying a coordinate; and a scale reader installed on the moving body, which detects the coordinate, and measures the movement distance of the moving body.

In an embodiment, the support unit includes: a support plate supporting the substrate; and a support shaft coupled to a bottom end of the support plate, and wherein the bottom end of the support plate couples to a bracket coupled to a side of the moving body.

In an embodiment, the substrate treating apparatus further includes: a gas supply unit configured to supply a gas to the treating space; and a plasma source generating a plasma by exciting the gas, and wherein the plasma source includes: a top edge electrode surrounding a circumference of the dielectric plate and positioned at an edge region of the substrate supported on the support plate; and a bottom edge electrode positioned below the top edge electrode to face the top edge electrode.

The inventive concept provides a substrate treating method. The substrate treating method includes taking in a substrate to a treating space to mount on a support unit; and upwardly moving the support unit after mounting the substrate on the support unit; determining whether the support unit moves normally after the upwardly moving the support unit; and treating the substrate by generating a plasma in the treating space, and wherein at the determining whether the support unit moves normally, before the plasma is generated at the treating space at the treating the substrate, whether a pulse distance matching a predetermined distance data according to a pulse value of a driving unit which pulse-moves a moving body which moves the support unit in a top/down direction, matches a movement distance of the moving body is determined, and an interlock is generated if the pulse distance and the movement distance is different.

In an embodiment, at the determining whether the support unit moves normally, a gap measurement unit irradiates a light to a bottom portion of a dielectric plate positioned above the support unit and a top portion of the support unit, and measures a gap between the dielectric plate and a substrate supported on the support unit, and the gap between the dielectric plate and the substrate supported on the support plate determines whether a reference gap predetermined according to a recipe for treating the substrate at the treating the substrate matches a measurement gap measured by the gap measurement unit.

In an embodiment, an interlock is generated if the measurement gap and the reference gap is different.

In an embodiment, a plasma according to the recipe is generated in the treating space to perform the treating the substrate if the measurement gap and the reference gap match.

In an embodiment, if the pulse distance and the movement distance match at the determining whether the support unit moves normally, whether an estimation gap matching with a predetermined gap data according to the pulse distance or the movement distance and the measurement gap match is determined, before the reference gap and measurement gap are compared.

In an embodiment, an interlock is generated if the estimation gap and the measurement gap are different, and if the estimation gap and the measurement gap match, whether the reference gap and the measurement gap match is determined.

In an embodiment, the plasma is generated at an edge region of a substrate supported on the support unit.

The inventive concept provides a substrate treating method. The substrate treating method includes taking in a substrate to a treating space to mount on a support unit; upwardly moving the support unit when the substrate is mounted on the support unit, so a gap between a top end of a substrate supported on the support unit and a bottom end of a dielectric plate positioned above the support unit to face the support unit matches a reference gap set according to a recipe; measuring the gap between the top end of the substrate supported on the support unit and the bottom end of the dielectric plate after the upwardly moving the support unit, to determine whether a measurement gap matches the reference gap; and treating the substrate according to the recipe by forming an electric field in the treating space, and wherein the treating the substrate is performed after the measurement gap and the reference gap is determined to be the same in the measuring the gap.

In an embodiment, if the measurement gap is larger than the reference gap, a bottom portion of the dielectric plate is determined to be damaged, and an interlock is generated and a maintenance work is performed on the dielectric plate.

In an embodiment, if the measurement gap is smaller than the reference gap, it is determined that foreign impurities are attached to a bottom portion of the dielectric plate, and an interlock is generated and a maintenance work is performed on the dielectric plate.

In an embodiment, if the measurement gap is different from the reference gap, it is determined that a movement of the support unit is abnormal, and an interlock is generated and a maintenance restoration operation is performed with respect to a driving unit for moving the support unit.

In an embodiment, if the measurement gap is different from the reference gap, it is determined that the substrate supported on the support unit is in a warpage state or a mounting state of the substrate is abnormal, so an interlock is generated.

In an embodiment, the gap measurement unit for measuring a gap between the dielectric plate and the support unit is installed on an outer wall of the housing which defines the treating space, and includes an irradiation unit for irradiating a light and a light receiving unit for receiving the light, and the measurement gap measures based on a light amount of the light receiving unit.

In an embodiment, the electric field is generated at an edge region of the substrate supported on the support unit, and excites a gas supplied to the treating space.

In an embodiment, the measuring the gap firstly determines whether a pulse distance which matches a predetermined distance data according to a pulse value of a driving unit which pulse-moves a moving body which moves the support unit in an up/down direction matches a movement distance of the moving body, before it determines whether the measurement gap matches the reference gap, and if the pulse distance matches the movement distance, whether the measurement gap and the reference gap match is determined.

According to an embodiment of the inventive concept, a substrate may be efficiently treated.

According to an embodiment of the inventive concept, whether a reference gap according to a recipe matches a gap between a substrate and a dielectric plate may be efficiently determined.

According to an embodiment of the inventive concept, components which need a maintenance can be efficiently determined.

According to an embodiment of the inventive concept, a time at which a maintenance is needed may be efficiently predicted.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 is a cross-sectional view schematically illustrating a substrate treating apparatus according to an embodiment.

FIG. 2 is a cross-sectional view of a frame schematically illustrating a driving unit, a pulse measurement unit, and a displacement measurement unit according to an embodiment.

FIG. 3 is a perspective view schematically illustrating the driving unit and the displacement measurement unit according to an embodiment.

FIG. 4 is a flowchart of a substrate treating method according to an embodiment.

FIG. 5 is a cross-sectional view schematically illustrating the substrate treating apparatus in which a treating step is performed according to an embodiment.

FIG. 6 is a flowchart of a determination step according to an embodiment.

FIG. 7 to FIG. 9 are enlarged views of the substrate treating apparatus when a measurement gap and a reference gap are different.

FIG. 10 to FIG. 12 are flowcharts of the determination step according to another embodiment.

### DETAILED DESCRIPTION

Example embodiments will now be described more fully with reference to the accompanying drawings. Example embodiments are provided so that this disclosure will be thorough and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

When the term “same” or “identical” is used in the description of example embodiments, it should be understood that some imprecisions may exist. Thus, when one element or value is referred to as being the same as another element or value, it should be understood that the element or value is the same as the other element or value within a manufacturing or operational tolerance range (e.g., ±10%).

When the terms “about” or “substantially” are used in connection with a numerical value, it should be understood that the associated numerical value includes a manufacturing or operational tolerance (e.g., ±10%) around the stated numerical value. Moreover, when the words “generally” and “substantially” are used in connection with a geometric shape, it should be understood that the precision of the geometric shape is not required but that latitude for the shape is within the scope of the disclosure.

Unless otherwise defined, all terms (including technical and scientific terms) used herein have the same meaning as commonly understood by one of ordinary skill in the art to which example embodiments belong. It will be further understood that terms, including those defined in commonly used dictionaries, should be interpreted as having a meaning that is consistent with their meaning in the context of the relevant art and will not be interpreted in an idealized or overly formal sense unless expressly so defined herein.

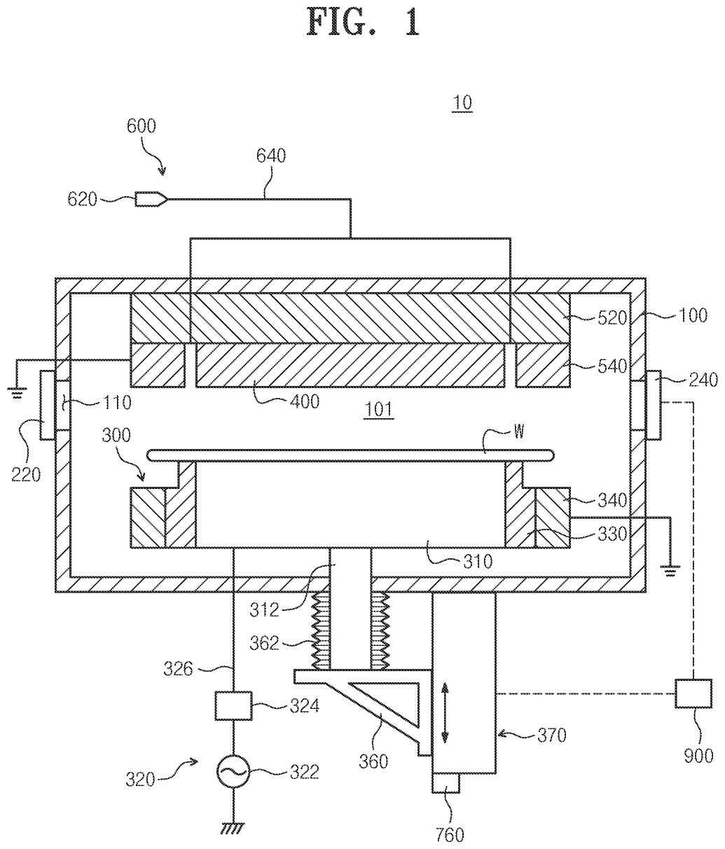

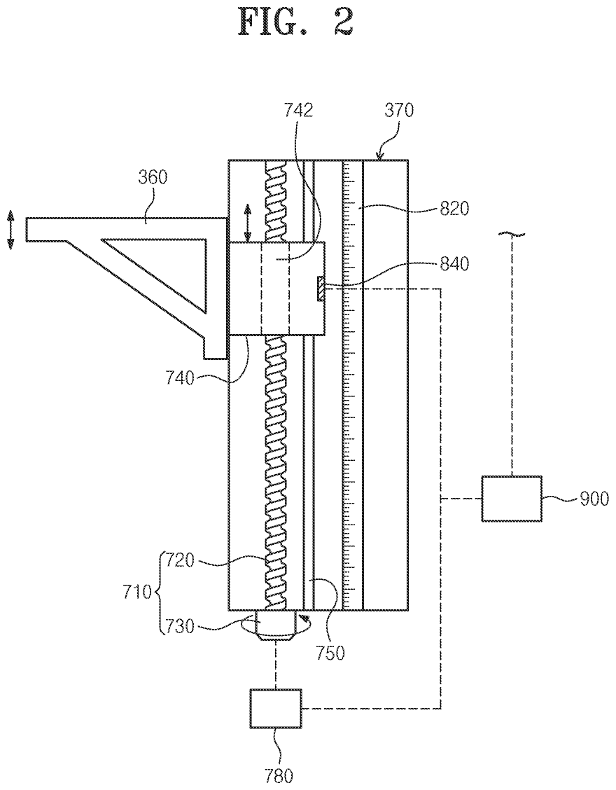

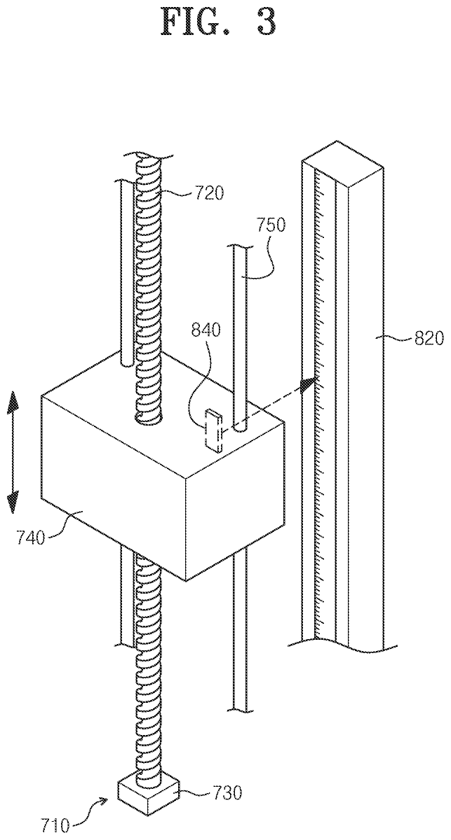

FIG. 1 is a cross-sectional view schematically illustrating a substrate treating apparatus according to an embodiment. FIG. 2 is a cross-sectional view of a frame schematically illustrating a driving unit, a pulse measurement unit, and a displacement measurement unit according to an embodiment. FIG. 3 is a perspective view schematically illustrating the driving unit and the displacement measurement unit according to an embodiment.

Hereinafter, the substrate treating apparatus 10 according to an embodiment of the inventive concept will be described in detail with reference to FIG. 1 to FIG. 3.

The substrate treating apparatus 10 performs a process treatment on the substrate W. The substrate treating apparatus 10 may perform a plasma treatment process on the substrate W. For example, the plasma treatment process performed on the substrate treating apparatus 10 may be an etching process for etching a film on the substrate W or an ashing process. The film may include various kinds of films such as a polysilicon film, an oxide film, a nitride film, a silicon oxide film, or a silicon nitride film. The oxide film described above may be a natural oxide film or a chemically generated oxide film. In addition, the film can be a foreign substance (byproduct) which occurs in a process of treating the substrate W and which attaches to and/or remains on the substrate W.

In the substrate treating apparatus 10 described below, a Bevel Etch process of removing a film on an edge region of the substrate W is described as an example. However, it is not limited to this, and the substrate treating apparatus 10 described below can be applied equally or similarly to various processes in which the substrate W is treated using a plasma.

The substrate treating apparatus 10 may include a housing 100, gap measurement units 220 and 240, a support unit 300, a dielectric plate 400, top electrode units 520 and 540, a gas supply unit 600, a driving unit 710, a pulse measurement unit 780, displacement measurement units 820 and 840, and a controller 900.

The housing 100 has a treating space 101 in which the substrate W is treated. The housing 100 may have a substantially hexahedral shape.

An opening (not shown) is formed on a sidewall of the housing 100. The substrate W may be taken into the treating space 101 through the opening (not shown) or taken out of the treating space 101. The opening (not shown) may be opened or closed by an opening/closing device such as a door assembly (not shown). When the opening (not shown) is closed after the substrate W is taken into the treating space 101, an atmosphere of the treating space 101 may be created at a low pressure close to a vacuum by a depressurization member (not shown).

In addition, a view port 110 is formed on a sidewall of the housing 100. The view port 110 is made of a transparent material. A plurality of view ports 110 are provided. For example, the view ports 110 may be provided to form a pair. For example, two view ports 110 may be formed on the sidewall of the housing 100. The view ports 110 formed on the sidewall of the housing 100 are positioned to face each other. Any one of the view ports 110 facing each other may function as a port through which a light irradiated by an irradiation unit 220 to be described later is transmitted. In addition, the other view port 110 among the view ports 110 facing each other can function as a port which transmits a light so that a light receiving unit 240 to be described later can receive the light irradiated by the irradiation unit 220.

According to an embodiment, when viewed from the front, a top end of the view port 110 may be positioned above a bottom end of the dielectric plate 400 to be described later. In addition, when viewed from the front, a bottom end of the view port 110 may be positioned below a top end of the substrate W supported on the support unit 200 described later. More specifically, the bottom end of the view port 110 may be positioned below the top end of the substrate W while the support plate 310 to be described later is upwardly moved to treat the substrate W (a state in which a gap between the top end of the substrate W supported on the support plate 310 and the dielectric plate 400 has become a reference gap) to be described later.

Unlike the aforementioned example, the view ports 110 may be provided with four or six (or an even number which is the same or higher), and each view port 110 may be positioned to face each other in pairs. In addition, some of the plurality of view ports 110 may function as a port which allows an operator to visually check the treating space 101.

The gap measurement units 220 and 240 measure a gap between the substrate W and the dielectric plate 400 to be described later. Specifically, the gap measurement units 220 and 240 can measure a gap, which is a vertical distance between the top end of the substrate W supported on the support unit 300 to be described later and the bottom end of the dielectric plate 400, based on an amount of light received by the light receiving unit 240 to be described later. According to an embodiment, the gap measurement units 220 and 240 may be a gap sensor which measures a gap using LED light.

The gap measurement units 220 and 240 include an irradiation unit 220 and a light receiving unit 240. The irradiation unit 220 irradiates a light. The light receiving unit 240 receives a light irradiated by the irradiation unit 220. The irradiation unit 220 and the light receiving unit 240 are installed on an outer wall of the housing 100. The light receiving unit 240 is disposed on an irradiation path of the light irradiated by the irradiation unit 220. The irradiation unit 220 is installed in any one of the plurality of view ports 110. The light receiving unit 240 is installed in the other view port 110 facing a view port 110 in which the irradiation unit 220 is installed among the plurality of view ports 110. Accordingly, the light irradiated by the irradiation unit 220 sequentially passes through any one view port 110 among the pair of view ports 110, the treating space 101, and a view port 110 facing a view port 110 at which the irradiation unit 220 is installed, to be transmitted to the light receiving unit 240.

The support unit 300 is positioned in the treating space 101. The support unit 300 supports the substrate W in the treating space 101. The support unit 300 may include a support plate 310, a power supply unit 320, an insulating ring 330, and a bottom edge electrode 340.

The substrate W is mounted on a top surface of the support plate 310. The support plate 310 may have a substantially circular shape when viewed from above. According to an embodiment, the support plate 310 may have a diameter smaller than that of the substrate W. Accordingly, a central region of the substrate W is mounted on the top surface of the support plate 310, and the edge region of the substrate W may not contact the top surface of the support plate 310.

The support plate 310 is coupled to a support shaft 312. The support shaft 312 is coupled to a bottom end of the support plate 310. The support shaft 312 has a vertical lengthwise direction. An end of the support shaft 312 is coupled to the support plate 310, and the other end penetrates an opening formed in a bottom wall of the housing 100. The other end of the support shaft 312 is connected to a top end of the bracket 360. The bracket 360 is positioned outside the housing 100. A bellows 362 is coupled to the bracket 360. The bellows 362 is coupled to the top end of the bracket 360 and the bottom wall of the housing 100, respectively. The bracket 360 may have a substantially upside-down 1′ shape. However, the inventive concept is not limited thereto, and the shape of the bracket 360 may be variously modified.

A moving body 740 to be described later is coupled to a side end of the bracket 360. The moving body 740 is positioned in an inner space of a frame 370, as described below. The frame 370 generally has a rectangular parallelepiped shape. In addition, the frame 370 may have a shape in which any one of the side surfaces is open. The bracket 360 is positioned on an open side of the frame 370. A top end of the frame 370 is connected to the bottom wall of the housing 100. The top end of the frame 370 may be connected to the bottom wall of the housing 100 using a fixing means such as a bolt and a nut, which are not shown.

The power supply unit 320 supplies a power to the support plate 310. The power supply unit 320 includes a power source 322, an impedance matcher 324, and a power line 326. The power source 322 may be a bias power source. In addition, the power source 322 may be an RF power source. The power source 322 may be electrically connected to the support plate 310 through the power line 326. The impedance matcher 324 may be installed on the power line 326 to match an impedance.

The insulating ring 330 is disposed between the support plate 310 and the bottom edge electrode 340 to be described later. According to an embodiment, the insulating ring 330 may be made of an insulating material. Accordingly, the insulating ring 330 electrically separates the support plate 310 from the bottom edge electrode 340. The insulating ring 330 generally has a ring shape. The insulating ring 330 is disposed to surround the support plate 310. Specifically, the insulating ring 330 is disposed to surround an outer circumferential surface of the support plate 310.

According to an embodiment, the insulating ring 330 may have a height of a top surface of an inner region thereof different from a height of a top surface of an outer region thereof. That is, the top surface of the insulating ring 330 may be formed to be stepped. For example, the insulating ring 330 may be stepped so that the height of the top surface of the inner region thereof is stepped higher than the height of the top surface of the outer region. When the substrate W is mounted on the support plate 310, a top surface of an inner region of the insulating ring 330 may be in contact with a bottom surface of the substrate W. On the other hand, even if the substrate W is mounted on the support plate 310, the top surface of the outer region of the insulating ring 330 may be spaced apart from the bottom surface of the substrate W.

The bottom edge electrode 340 may be grounded. A material of the bottom edge electrode 340 may include a metal. The bottom edge electrode 340 generally has a ring shape. The bottom edge electrode 340 is disposed to surround an outer circumferential surface of the insulating ring 330. The bottom edge electrode 340 is positioned in the edge region of the substrate W supported on the support plate 310 when viewed from above. More specifically, the bottom edge electrode 340 is positioned below the edge region of the substrate W supported on the support plate 310.

A top surface of the bottom edge electrode 340 may be positioned at the same height as the top surface of the outer region of the insulating ring 330. In addition, the top surface of the bottom edge electrode 340 may be positioned at a lower height than the top surface of the support plate 310. Accordingly, the bottom edge electrode 340 may be spaced apart from the bottom surface of the substrate W supported on the support plate 310. Specifically, the bottom edge electrode 340 may be spaced apart from the bottom surface of the edge region of the substrate W supported on the support plate 310. A plasma to be described later may penetrate a space between the bottom surface of the edge region of the substrate W and the bottom edge electrode 340. In addition, the bottom surface of the bottom edge electrode 340 may be positioned at the same height as a bottom surface of the insulating ring 330.

The dielectric plate 400 may be a disk-shaped dielectric substance. The dielectric plate 400 is disposed to face the support unit 300. More specifically, the dielectric plate 400 is disposed above the support plate 310 and is disposed to face the support plate 310. That is, a bottom surface of the dielectric plate 400 faces the top surface of the support plate 310. The dielectric plate 400 may be coupled to a plate 520 to be described later and fixed in the treating space 101.

The top electrode units 520 and 540 are disposed in the treating space 101. In addition, the top electrode units 520 and 540 are disposed above the support unit 300. The top electrode units 520 and 540 may include a plate 520 and a top edge electrode 540.

The material of the plate 520 may include a metal. According to an embodiment, the material of the plate 520 may include an aluminum. The plate 520 may be coupled to a ceiling wall of the housing 100. The plate 520 may have a disk shape. A diameter of the plate 520 may be greater than a diameter of the dielectric plate 400. In addition, a central axis of the plate 520 may be coaxial with a central axis of the dielectric plate 400. The dielectric plate 400 is coupled to a bottom end of the plate 520. In addition, the top edge electrode 540 is coupled to a bottom end of the plate 520. Specifically, the dielectric plate 400 may be coupled to a bottom central region of the plate 520, and the top edge electrode 540 may be coupled to a bottom edge region of the plate 520.

The top edge electrode 540 generally has a ring shape. The top edge electrode 540 is disposed to surround an outer circumferential surface of the dielectric plate 400. In addition, an inner circumferential surface of the top edge electrode 540 is disposed to be spaced apart from the outer circumferential surface of the dielectric plate 400 by a predetermined distance. A gas line 640 to be described later is connected to a space between the top edge electrode 540 and the dielectric plate 400. The space between the top edge electrode 540 and the dielectric plate 400 overlaps the edge region of the substrate W when viewed from above.

In addition, the top edge electrode 540 is disposed above the edge region of the substrate W. In addition, the top edge electrode 540 is disposed to face the bottom edge electrode 340 above the bottom edge electrode 340. Accordingly, when viewed from above, the top edge electrode 540 may overlap the edge region of the substrate W supported on the support plate 310.

The top edge electrode 540 may be grounded. The material of the top edge electrode 540 may include a metal. The bottom edge electrode 340 and the top edge electrode 540 described above may function as a plasma source for generating a plasma in the treating space 101. The bottom edge electrode 340 can generate the plasma in the edge region of the substrate W by exciting a gas supplied to the treating space 101 along with the top edge electrode 540. The top edge electrode 540 and the bottom edge electrode 340 may induce a coupling of a bias power or a high-frequency power applied to the support plate 310 to increase a density of an electric field or plasma generated in the edge region of the substrate W.

The gas supply unit 600 supplies the gas to the treating space 101. A gas supplied by the gas supply unit 600 may be a gas excited by the plasma. The gas supply unit 600 may include a gas source 620 and a gas line 640.

The gas source 620 stores the gas. An end of the gas line 640 may be connected to the gas source 620, and the other end may be connected to the space between the top edge electrode 540 and the dielectric plate 400. The gas stored in the gas source 620 passes sequentially through the gas line 640 and the space between the top edge electrode 540 and the dielectric plate 400, and is supplied to the edge region of the substrate W.

The driving unit 710 lifts and lowers the moving body 740 to be described later. The driving unit 710 linearly moves the moving body 740 in an upward or downward direction. The driving unit 710 may include a ball thread 720 and a driving motor 730.

The ball thread 720 may be positioned inside the frame 370. The ball thread 720 has a vertical lengthwise direction. The ball thread 720 is coupled to the driving motor 730. The driving motor 730 may be coupled to a bottom end of the frame 370. However, the inventive concept is not limited thereto, and the driving motor 730 may be disposed in an inner space of the frame 370. The driving motor 730 transmits a driving force to the ball thread 720. The driving motor 730 may rotate the ball thread 720. According to an embodiment, the driving motor 730 may be a pulse motor.

The moving body 740 may be positioned inside the frame 370. The moving body 740 is coupled to the bracket 360. For example, a side end of the moving body 740 is connected to the side end of the bracket 360. A nut portion 742 may be formed inside the moving body 740. The nut portion 742 formed in the moving body 740 may penetrate a top surface and a bottom surface of the moving body 740. The nut portion 742 is screw-coupled to the ball thread 720. As the above-described driving motor 730 transmits a rotational force to the ball thread 720, the moving body 740 may pulse move.

The guide rail 750 guides a moving direction of the moving body 740. The moving body 740 may pulse-move along a lengthwise direction of the guide rail 750. The guide rail 750 is disposed inside the frame 370. The guide rail 750 has a lengthwise direction parallel to the ball thread 720. That is, the guide rail 750 has a vertical lengthwise direction. In addition, the guide rail 750 is disposed adjacent to the ball thread 720. According to an embodiment, a plurality of guide rails 750 may be provided. The plurality of guide rails 750 may be disposed with the ball thread 720 interposed therebetween.

Accordingly, as the driving motor 730 transmits a rotational force to the ball thread 720, the moving body 740 may pulse move along the lengthwise direction of the guide rail 750. The bracket 360 may also pulse move in the top/down direction by a pulse movement of the moving body 740, and the support shaft 312 and the support plate 310 connected to the bracket 360 may pulse in the top/down direction.

Unlike the aforementioned example, the driving unit 710 according to an embodiment can be variously modified into a known motor such as a linear motor which can pulse move the moving body 740 in the top/down direction.

The pulse measurement unit 780 records a pulse value of the driving motor 730. The pulse measurement unit 780 may be electrically connected to the driving motor 730. For example, the pulse measurement unit 780 may be connected to the driving motor 730 in a wired or wireless manner. According to an embodiment, the pulse measurement unit 780 may be an encoder.

The pulse measurement unit 780 may record the pulse value of the driving motor 730 and measure a pulse distance matching a predetermined distance data according to a recorded pulse value. A predetermined distance data may mean a linear distance at which the moving body 740 moves according to an angle the driving motor 730 rotates, if the driving motor 730 rotates at a certain angle by one pulse input. For example, if the drive motor 730 pulse moves the moving body 740 five times, the pulse measurement unit 780 can measure the pulse distance at five times the value of the linear distance that the moving body 740 can move by one pulse input. That is, the pulse distance measured by the pulse measurement unit 780 may be an estimated value of the actual movement distance of the moving body 740.

The displacement measurement unit 800 measures the movement distance of the moving body 740. More specifically, the displacement measurement unit 800 may measure an actual movement distance of the moving body 740. The displacement measurement unit 800 includes a linear scale 820 and a scale reader 840.

The linear scale 820 may be positioned inside the frame 370. The linear scale 820 has a lengthwise direction parallel to the guide rail 750. That is, the linear scale 820 has a vertical lengthwise direction. The linear scale 820 is disposed adjacent to the ball thread 720. In addition, the linear scale 820 is disposed adjacent to the guide rail 750. In addition, the linear scale 820 is disposed outside the moving path of the moving body 740. That is, when viewed from above, the linear scale 820 is disposed at a position that does not overlap the moving body 740. At a side surface facing the moving body 740 among side surfaces of the linear scale 820, coordinates are displayed. For example, a mechanical coordinate system may be displayed on the linear scale 820.

The scale reader 840 is installed on the moving body 740. More specifically, the scale reader 840 is installed on a side surface of the moving body 740 facing the linear scale 820. The scale reader 840 is installed on the moving body 740 to detect a coordinate displayed on the linear scale 820. The scale reader 840 may measure an actual movement distance of the moving body 740 according to a coordinate value detected by the scale reader 840. That is, the scale reader 840 may measure the actual movement distance of the moving body 740 in the top/down direction.

The controller 900 may control components included in the substrate treating apparatus 10. In addition, the controller 900 may receive a data on the gap (hereinafter, referred to as the measurement gap) measured by the gap measurement units 220 and 240. In addition, the controller 900 may receive a data on the pulse distance from the pulse measurement unit 780. In addition, the controller 900 may receive the data on the movement distance from the scale reader 840. The controller 900 may determine whether a received pulse distance matches the movement distance. In addition, the controller 900 may calculate an estimation gap matching with a predetermined gap data according to a pulse distance or a movement distance. In addition, the controller 900 may determine whether the estimation gap matches the measurement gap. In addition, the controller 900 may determine whether the estimation gap or the measurement gap matches the reference gap. The controller 900 may be connected to the aforementioned light receiving unit 240, the pulse measurement unit 780 and the scale reader 840 in a wired or wireless manner, respectively.

Using a data transmitted from the light receiving unit 240, the pulse measurement unit 780, or the scale reader 840, the controller 900 can control the components included in the substrate treating apparatus 10 to perform the substrate treating method described below.

The controller 900 may comprise a process controller consisting of a microprocessor (computer) that executes a control of the substrate treating apparatus 10, a user interface such as a keyboard via which an operator inputs commands to manage the substrate treating apparatus, or a memory unit storing a treating recipe including a control program executed by controlling the process controller or a program to execute components according to data and treating conditions. In addition, the user interface and the memory unit may be connected to the process controller.

Hereinafter, a substrate treating method according to an embodiment of the inventive concept will be described in detail. Since the substrate treating method according to the embodiment described below is performed by the substrate treating apparatus 10 described with reference to FIG. 1 to FIG. 3, the reference numerals cited in FIG. 1 to FIG. 3 are cited in the same way.

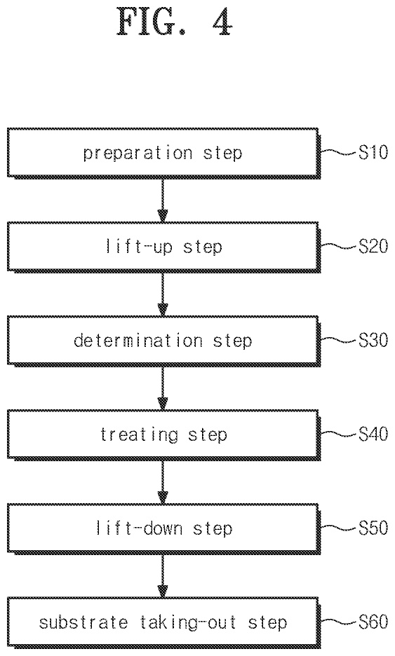

FIG. 4 is a flowchart of a substrate treating method according to an embodiment.

Referring to FIG. 4, the substrate treating method according to an embodiment includes a preparation step S10, a lift-up step S20, a determination step S30, a treating step S40, a lift-down step S50, and a substrate taking-out step S60. The preparation step S10, the lift-up step S20, the determination step S30, the treating step S40, the lift-down step S50, and the substrate taking-out step S60 may be performed in the order of time series.

In the preparation step S10, the substrate W is taken into the treating space 101. A transfer robot which is not shown takes the substrate W into the treating space 101 through an opening (not shown) formed on the sidewall of the housing 100. The substrate W taken into the treating space 101 is mounted on the top surface of the support plate 310.

In the lift-up step S20, the support unit 300 can be upwardly moved to narrow the gap between the substrate W supported on the support plate 310 and the dielectric plate 400. More specifically, the driving motor 730 rotates the ball thread 720, and accordingly, the moving body 740 pulse-moves in the upward direction, so that the support unit 300 can pulse-move in the upward direction as well. According to an embodiment, the driving unit 710 upwardly moves the support unit 300 so that the gap between the top end of the substrate W supported on the support unit 300 and the bottom end of the dielectric plate 400 becomes a reference gap. The reference gap may be a vertical distance between the top end of the substrate W and the bottom end of the dielectric plate 400, based on a recipe in which the substrate W will be treated in the treating step S40 described later.

In the determination step S30, it may be determined whether the support unit 300 moves normally. In addition, in the determination step S30, the gap between the top end of the substrate W supported on the support unit 300 and the bottom end of the dielectric plate 400 can be measured, and whether a measured actual gap matches the reference gap can be determined. A detailed description of the determination step S30 will be described later.

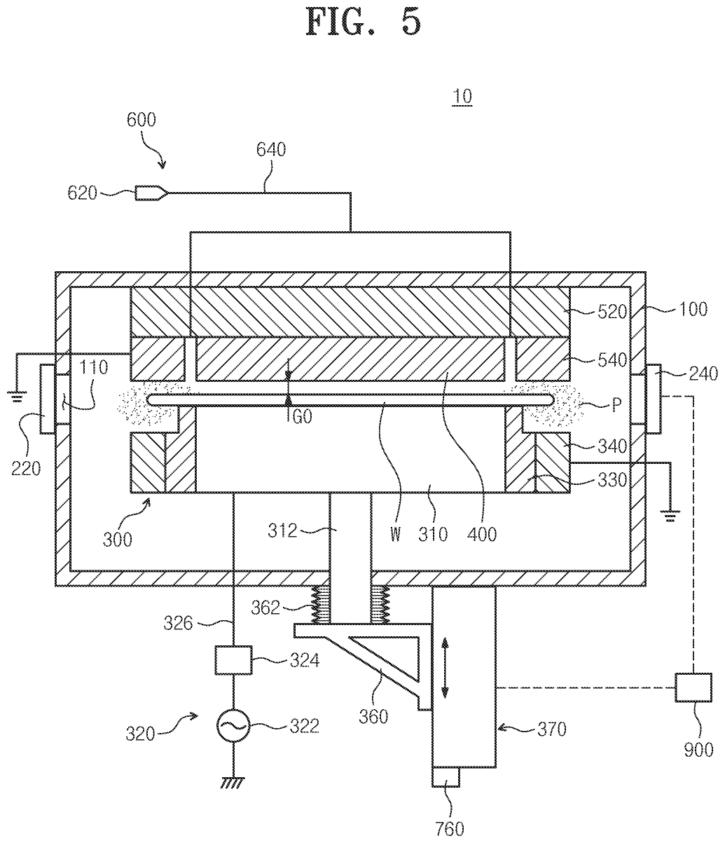

FIG. 5 is a cross-sectional view schematically illustrating the substrate treating apparatus in which a treating step is performed according to an embodiment.

Referring to FIG. 4 and FIG. 5, if it is determined that the actual gap between the top end of the substrate W supported on the support unit 300 and the bottom end of the dielectric plate 400 matches a reference gap G0 in the determination step S30, the treating step S40 is performed.

In the treating step S40, the substrate W may be treated by generating a plasma in the edge region of the substrate W. More specifically, the gas supplied to the edge region of the substrate W by the gas supply unit 600 is excited to a plasma P state by a plasma source to treat the edge region of the substrate W. For example, the film formed in the edge region of the substrate W may be etched by the plasma P.

When a predetermined treatment on the edge region of the substrate W is completed, the lift-down step S50 is performed. In the lift-down step S50, the support unit 300 downwardly moves to widen the gap between the top end of the substrate W and the bottom end of the dielectric plate 400. When the gap between the top end of the substrate W and the bottom end of the dielectric plate 400 widens enough for the transfer robot (not shown) to move between the gaps, the substrate taking-out step S60 is performed. The transfer robot (not shown) takes out the substrate W from the treating space 101.

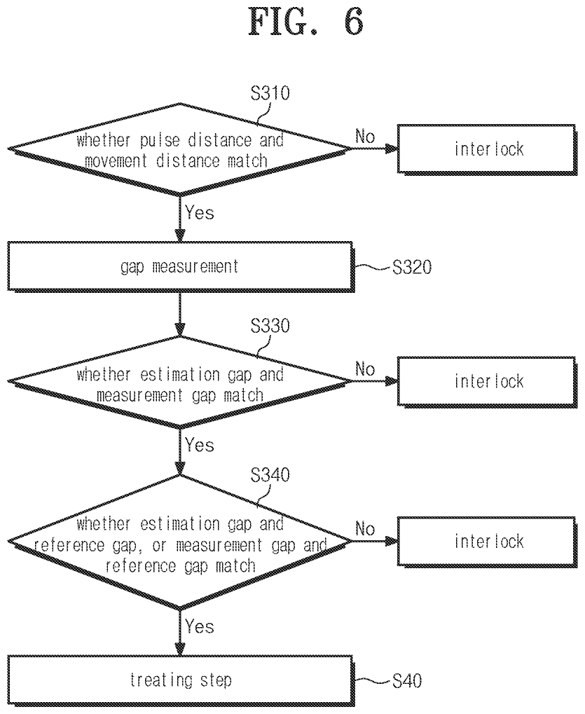

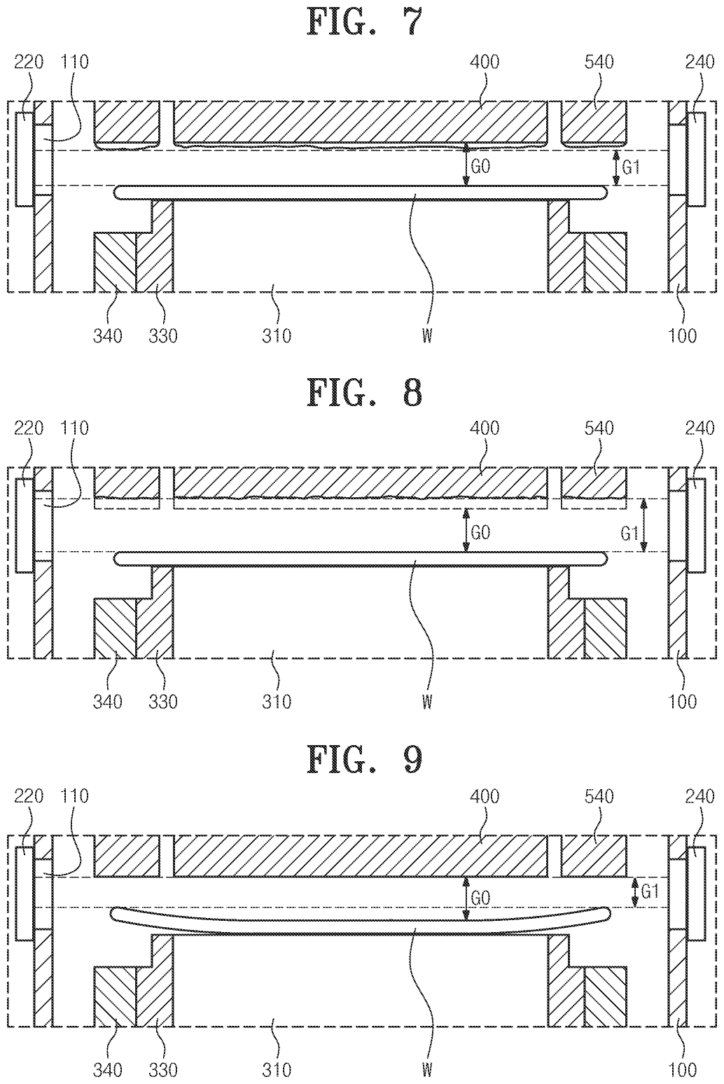

FIG. 6 is a flowchart of a determination step according to an embodiment. FIG. 7 to FIG. 9 are enlarged views of the substrate treating apparatus when a measurement gap and a reference gap are different.

The determination step S30 determines whether the pulse distance matches the movement distance S310. The pulse distance may be a distance matched with a predetermined distance data according to a pulse value of the driving motor 730. That is, the pulse distance may be an estimated value of the actual movement distance of the moving body 740 measured by the pulse measurement unit 780 as described above. In addition, the movement distance may mean the actual movement distance of the moving body 740 measured according to the coordinate value detected by the scale reader 840.

If it is determined that the pulse distance and the movement distance do not match, an interlock may be generated to perform a maintenance work on the substrate treating apparatus 10. If the pulse distance and the movement distance do not match, it may be determined that a problem has occurred in the components contributing to a top/down movement of the support unit 300. Accordingly, if the pulse distance and the movement distance do not match, an interlock may be generated and a maintenance work may be performed on components that contribute to a top/down movement of the support unit 300. For example, if the pulse distance and the movement distance do not match, an interlock can be generated, and whether foreign substances are attached to the driving unit 710, the moving body 740, the nut portion 742, or the guide rail 750, or if a damage has occurred on the driving 710, etc. are investigated, and a respective maintenance work can be performed.

That is, according to an embodiment of the inventive concept, by determining whether the pulse distance and the movement distance match, it is possible to quickly determine that there is a problem with the components contributing to the top/down movement of the support unit 300, so a maintenance work can be performed efficiently.

If it is determined that the pulse distance and the movement distance match, the gap measurement units 220 and 240 measure the gap between the bottom end of the dielectric plate 400 and the top end of the substrate W supported on the support unit 300 S320. As described above, the irradiation unit 220 irradiates a light toward the light receiving unit 240, and the light receiving unit 240 receives the light. Based on a received light amount data, the light receiving unit 240 measures the gap (hereinafter referred to as a measurement gap), which is a vertical distance between the top end of the substrate W supported on the support unit 300 and the bottom end of the dielectric plate 400.

In addition, an estimation gap matching a predetermined gap data is calculated according to the pulse distance and the movement distance. In general, in the lift-up step S20 (see FIG. 4), the support unit 300 is upwardly moved so that the gap between the bottom end of the dielectric plate 400 and the top end of the substrate W supported on the support unit 300 matches the reference gap G0 set according to a recipe. Therefore, in general, if it is determined that the pulse distance and the movement distance match, the estimation gap matching the predetermined gap data according to the pulse distance or the movement distance will match the reference gap G0.

However, even if it is determined that the pulse distance and the movement distance match, problems may occur in both the driving unit 710 and the displacement measurement unit 820 and 840, and the estimation gap may not match the reference gap G0. According to an embodiment of the inventive concept, whether the measurement gap measured by the gap measurement units 220 and 240 matches the estimation gap S330 is preemptively determined.

If it is determined that the measurement gap and the estimation gap do not match, an interlock may be generated to perform a maintenance work on the substrate treating apparatus 10. If it is determined that the measurement gap and the estimation gap are inconsistent, it can be determined that there is a problem with the components that contribute to a top/down movement of the support unit 300, or that there is a problem with the dielectric plate 400 or the top edge electrode 540. More preferably, since the pulse distance and the movement distance have been previously confirmed to match, if the measurement gap and the estimation gap are found to be inconsistent, there is a high possibility of a problem in the dielectric plate 400 or the top edge electrode 540. In this case, whether there is a damage or whether foreign foreign substances are attached to the dielectric plate 400 or the top edge electrode 540 is preemptively checked, and if it is determined that there is no problem with the dielectric plate 400 or the top edge electrode 540, an inspection on the components that contribute to the top/down movement of the support unit 300 can be performed.

When it is determined that the measurement gap and the estimation gap match, it may be determined whether the estimation gap (or the measurement gap) matches the reference gap G0 S340. The reference gap G0 is a predetermined value according to a predetermined recipe in a subsequent treating step S40 as described above. When the estimation gap (or measurement gap) coincides with the reference gap G0, the treating step S40 is performed. In other words, it is possible to determine once more whether the estimation gap (or measurement gap) and the reference gap G0 match each other, and a precise treatment of the substrate W according to the recipe may be performed.

On the other hand, if the estimation gap (or measurement gap) is determined to not match the reference gap G0, an interlock is generated and a maintenance work is performed on the dielectric plate 400 or the top edge electrode 540.

For example, as described in FIG. 7, if the measurement gap G1 is determined to have a value smaller than the reference gap G0, it is determined that a large amount of foreign substances are attached to the bottom of the dielectric plate 400 or the top edge electrode 540. In this case, the operator may perform a maintenance work on the dielectric plate 400 or the top edge electrode 540.

In addition, as described in FIG. 8, if the measurement gap G1 is determined to have a value greater than the reference gap G0, a bottom portion of the dielectric plate 400 or a bottom portion of the top edge electrode 540 is determined to be damaged. In this case, the operator may replace the dielectric plate 400 or the top edge electrode 540.

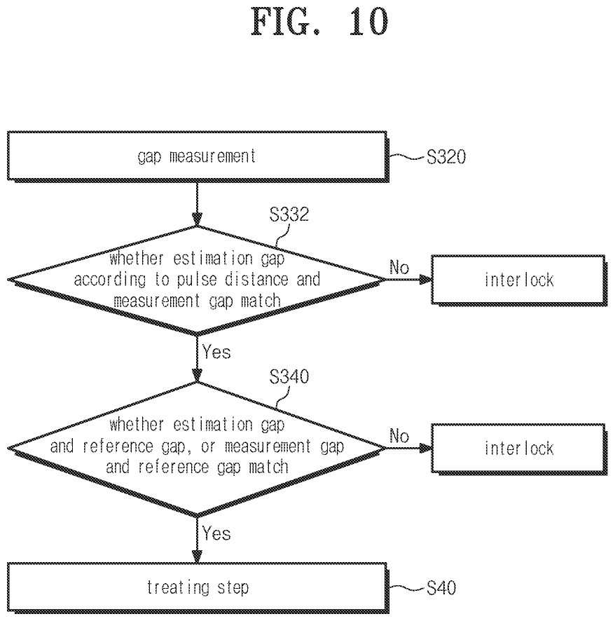

In addition, as described in FIG. 9, if the measurement gap G1 is determined to have a value smaller than the reference gap G0, it may be determined that the substrate W mounted on the top surface of the support plate 310 is in a bent state. Although not shown, if the measurement gap has a value smaller than the reference gap, it may be determined that the substrate is not accurately mounted on the top surface of the support plate.

If the dielectric plate 400 or the top edge electrode 540 is checked because the estimation gap (or measurement gap) is not consistent with the reference gap G0, but there is no problem with the dielectric plate 400 or the top edge electrode 540, the operator can subsequently check the driving unit 710.

Hereinafter, a determination step according to another embodiment of the inventive concept will be described. Since the determination step according to an embodiment described below is mostly performed by the same mechanism as the determination step except for additional description, a description of overlapping contents will be omitted.

FIG. 10 to FIG. 12 are flowcharts of the determination step according to another embodiment.

Referring to FIG. 10, the measurement gap measured by the gap measurement unit 220 and 240 is matched with predetermined gap data according to the pulse distance to determine whether the calculated estimation gap matches S322. If the measurement gap and the estimation gap do not match, an interlock is generated, and the operator preemptively checks and maintains the components that contribute to the top/down movement of the support unit 300.

When the measurement gap and the estimation gap coincide, it is determined whether the measurement gap (or estimation gap) matches the reference gap S340. If the measurement gap and the reference gap match each other, the treating step S40 is performed, if the measurement gap and the reference gap do not match each other, an interlock is generated, and the operator preemptively checks and maintains the dielectric plate 400 or the top edge electrode 540.

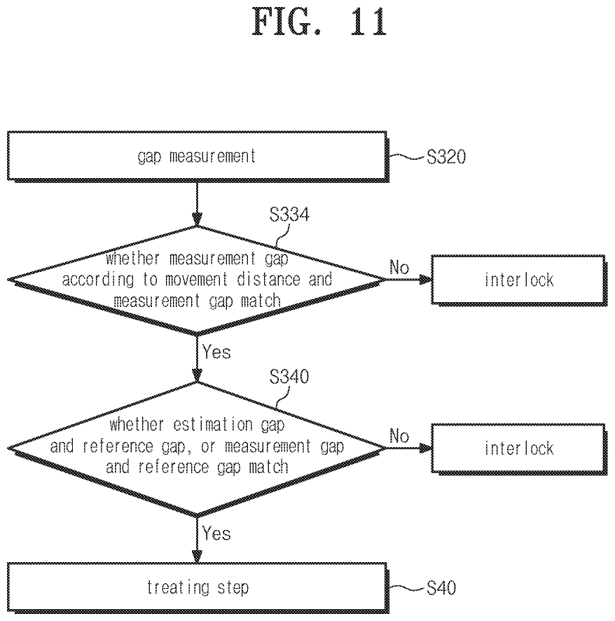

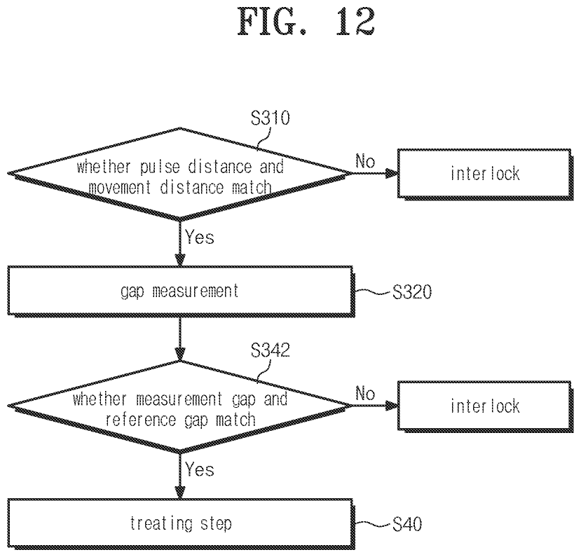

Referring to FIG. 11, the measurement gap measured by the gap measurement units 220 and 240 is matched with predetermined gap data according to the movement distance to determine whether the calculated estimation gap matches S334. The mechanism after determining whether the measurement gap matches the estimation gap is the same as or similar to the embodiment described with reference to FIG. 10.

Referring to FIG. 12, it is determined whether the pulse distance matches the movement distance S310. If it is determined that the pulse distance and the movement distance do not match, an interlock is generated to check and maintain the components that contribute to the top/down movement of the support unit 300. When it is determined that the pulse distance and the movement distance match, the gap measurement units 220 and 240 measure the gap between the top end of the substrate supported on the support plate 310 and the bottom end of the dielectric plate 400 S320. The gap measurement units 220 and 240 determine whether the measurement gap which is measured matches the reference gap S342. If it is determined that the measurement gap and the reference gap do not match, the dielectric plate 400, the top edge electrode 540, and the substrate W are inspected and maintained. Unlike this, when it is determined that the measurement gap and the reference gap coincide with each other, the treating step S40 is performed.

That is, in an embodiment of the inventive concept, the estimation gap is not calculated, but whether the pulse distance and the movement distance match, and whether the measurement gap and the reference gap match are determined. Depending on whether the pulse distance and the movement distance match, it is possible to primarily determine whether a problem occurs with the components contributing to the top/down movement of the support unit 300. In addition, depending on whether the measurement gap and the reference gap match, the dielectric plate 400, the top edge electrode 540, or a mounting state of the substrate W, a bending state of the substrate W, etc. can be secondarily determined.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating apparatus comprising:
a housing having a treating space for treating a substrate;
a support unit configured to support the substrate within the treating space;
a dielectric plate positioned above the support unit facing the support unit;
a gap determination unit configured to measure a gap between a substrate supported on the support unit and the dielectric plate;
a driving unit configured to pulse-move a moving body which moves the support unit in a top/down direction;
a pulse measurement unit configured to record a pulse value of the driving unit; and
a displacement measurement unit configured to measure a movement distance of the moving body.

2. The substrate treating apparatus of claim 1, further comprising at least a pair of view ports formed to face each other on a sidewall of the housing, and
wherein the gap measurement unit includes:
an irradiation unit installed at any one view point among the view ports and configured to irradiate a light; and
a light receiving unit installed at the other view point among the view ports and configured to receive the light.

3. The substrate treating apparatus of claim 1, wherein the driving unit includes:
a ball screw which is screw-coupled to a nut unit formed within the moving body which moves along a guide rail having a top/down lengthwise direction; and
a driving motor which pulse-moves the moving body by rotating the ball screw, and
wherein the pulse measurement unit includes an encoder which measures a pulse value of the driving motor, and measures a pulse distance which matches a distance data which is predetermined according to the pulse value, and
the displacement measurement unit includes:
a linear scale positioned adjacent to the guide rail, having a lengthwise direction parallel to a lengthwise direction of the guide rail, and displaying a coordinate; and
a scale reader installed on the moving body, which detects the coordinate, and measures the movement distance of the moving body.

4. The substrate treating apparatus of claim 3, wherein the support unit includes:
a support plate supporting the substrate; and
a support shaft coupled to a bottom end of the support plate, and
wherein the bottom end of the support plate couples to a bracket coupled to a side of the moving body.

5. The substrate treating apparatus of claim 1, further comprising:
a gas supply unit configured to supply a gas to the treating space; and
a plasma source generating a plasma by exciting the gas, and
wherein the plasma source includes:
a top edge electrode surrounding a circumference of the dielectric plate and positioned at an edge region of the substrate supported on the support plate; and
a bottom edge electrode positioned below the top edge electrode to face the top edge electrode.

6. A substrate treating method comprising:
taking in a substrate to a treating space to mount on a support unit; and
upwardly moving the support unit after mounting the substrate on the support unit;
determining whether the support unit moves normally after the upwardly moving the support unit; and
treating the substrate by generating a plasma in the treating space, and wherein at the determining whether the support unit moves normally, before the plasma is generated at the treating space at the treating the substrate, whether a pulse distance matching a predetermined distance data according to a pulse value of a driving unit which pulse-moves a moving body which moves the support unit in a top/down direction, matches a movement distance of the moving body is determined, and
an interlock is generated if the pulse distance and the movement distance is different.

7. The substrate treating method of claim 6, wherein at the determining whether the support unit moves normally, a gap measurement unit irradiates a light to a bottom portion of a dielectric plate positioned above the support unit and a top portion of the support unit, and measures a gap between the dielectric plate and a substrate supported on the support unit, and
the gap between the dielectric plate and the substrate supported on the support plate determines whether a reference gap predetermined according to a recipe for treating the substrate at the treating the substrate matches a measurement gap measured by the gap measurement unit.

8. The substrate treating method of claim 7, wherein an interlock is generated if the measurement gap and the reference gap is different.

9. The substrate treating method of claim 7, wherein a plasma according to the recipe is generated in the treating space to perform the treating the substrate if the measurement gap and the reference gap match.

10. The substrate treating method of claim 7, wherein if the pulse distance and the movement distance match at the determining whether the support unit moves normally,
whether an estimation gap matching with a predetermined gap data according to the pulse distance or the movement distance and the measurement gap match is determined, before the reference gap and measurement gap are compared.

11. The substrate treating method of claim 10, wherein:
an interlock is generated if the estimation gap and the measurement gap are different, and
if the estimation gap and the measurement gap match, whether the reference gap and the measurement gap match is determined.

12. The substrate treating method of claim 6, wherein the plasma is generated at an edge region of a substrate supported on the support unit.

13. A substrate treating method comprising:
taking in a substrate to a treating space to mount on a support unit;
upwardly moving the support unit when the substrate is mounted on the support unit, so a gap between a top end of a substrate supported on the support unit and a bottom end of a dielectric plate positioned above the support unit to face the support unit matches a reference gap set according to a recipe;
measuring the gap between the top end of the substrate supported on the support unit and the bottom end of the dielectric plate after the upwardly moving the support unit, to determine whether a measurement gap matches the reference gap; and
treating the substrate according to the recipe by forming an electric field in the treating space, and
wherein the treating the substrate is performed after the measurement gap and the reference gap is determined to be the same in the measuring the gap.

14. The substrate treating method of claim 13, wherein if the measurement gap is larger than the reference gap, a bottom portion of the dielectric plate is determined to be damaged, and an interlock is generated and a maintenance work is performed on the dielectric plate.

15. The substrate treating method of claim 13, wherein if the measurement gap is smaller than the reference gap, it is determined that foreign impurities are attached to a bottom portion of the dielectric plate, and an interlock is generated and a maintenance work is performed on the dielectric plate.

16. The substrate treating method of claim 13, wherein if the measurement gap is different from the reference gap, it is determined that a movement of the support unit is abnormal, and an interlock is generated and a maintenance restoration operation is performed with respect to a driving unit for moving the support unit.

17. The substrate treating method of claim 13, wherein if the measurement gap is different from the reference gap, it is determined that the substrate supported on the support unit is in a warpage state or a mounting state of the substrate is abnormal, so an interlock is generated.

18. The substrate treating method of claim 13, wherein the gap measurement unit for measuring a gap between the dielectric plate and the support unit is installed on an outer wall of the housing which defines the treating space, and includes an irradiation unit for irradiating a light and a light receiving unit for receiving the light, and
the measurement gap measures based on a light amount of the light receiving unit.

19. The substrate treating method of claim 13, wherein the electric field is generated at an edge region of the substrate supported on the support unit, and excites a gas supplied to the treating space.

20. The substrate treating method of claim 13, wherein the measuring the gap firstly determines whether a pulse distance which matches a predetermined distance data according to a pulse value of a driving unit which pulse-moves a moving body which moves the support unit in an up/down direction matches a movement distance of the moving body, before it determines whether the measurement gap matches the reference gap, and
if the pulse distance matches the movement distance, whether the measurement gap and the reference gap match is determined.
